(19) United States
(12) Patent Application Publication
(10) Pub. No.: US 2024/0112998 A1
(43) Pub. Date: Apr. 4, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Yongjae KIM, Suwon-si (KR); Sungwoo PARK, Suwon-si (KR); Seungkwan RYU, Suwon-si (KR); Yanggyoo JUNG, Suwon-si (KR)

(21) Appl. No.: 18/461,569

(22) Filed: Sep. 6, 2023

(30) Foreign Application Priority Data
Sep. 30, 2022 (KR) 10-2022-0125042

(51) Int. Cl. H01L 23/498; H01L 23/00; H01L 23/31; H01L 23/538

(52) U.S. Cl. CPC H01L 23/49816; H01L 23/3128; H01L 23/5383; H01L 23/5385; H01L 24/13; H01L 24/16; H01L 24/32; H01L 24/73; H01L 2224/13147; H01L 2224/16227; H01L 2224/32225; H01L 2224/73204

(57) ABSTRACT

A semiconductor package includes a package substrate, an interposer mounted on the package substrate via first conductive bumps, first and second semiconductor devices disposed spaced apart from each other on the interposer and mounted on the interposer via second conductive bumps, and an underfill member filling a space between the first conductive bumps that are between the package substrate and the interposer. The interposer includes a central region and a peripheral region at least partially surrounding the central region. The first conductive bumps include first bump structures disposed on second bonding pads, which are in the central region and on a lower surface of the interposer, respectively, and having a circular shape. The first conductive bumps further include second bump structures disposed on second bonding pads, which are in the peripheral region and on the lower surface of the interposer, respectively, and having an elliptical shape.

### CROSS-REFERENCE TO RELATED APPLICATION

This application claims priority under 35 U.S.C. § 119 to Korean Patent Application No. 10-2022-0125042, filed on Sep. 30, 2022 in the Korean Intellectual Property Office (KIPO), the disclosure of which is herein incorporated by reference herein in its entirety.

### TECHNICAL FIELD

Example embodiments of the present inventive concept relate to a semiconductor package and a method of manufacturing the semiconductor package. More particularly, example embodiments of the present inventive concept relate to a semiconductor package including a plurality of different chips stacked on a package substrate by using an interposer and a method of manufacturing the same.

### DISCUSSION OF THE RELATED ART

Generally, electronic devices may include a high bandwidth memory (HBM) or a stacked chip package to provide an electronic device with high performance such as a high capacitance and a high speed operation. For example, a package used for such an electronic device may be provided with a high density interconnection using an extra substrate, such as a silicon interposer. However, when the interposer is mounted on a package substrate via conductive bumps, a misalignment between the interposer and the package substrate may occur due to a small pitch between the conductive bumps, and voids may be generated in a central region of the interposer when an underfill process for forming an underfill member between the interposer and the package substrate is performed.

### SUMMARY

According to an example embodiment of the present inventive concept, a semiconductor package includes: a package substrate; an interposer including a substrate, a wiring layer, first bonding pads, second bonding pads, and first conductive bumps, wherein the substrate has a plurality of through electrodes formed to penetrate therethrough, wherein the wiring layer is provided on an upper surface of the substrate and has a plurality of wirings electrically connected to the plurality of through electrodes, wherein the first bonding pads are provided on the wiring layer and are electrically connected to the plurality of wirings, wherein the second bonding pads are provided on a lower surface of the substrate and are electrically connected to the plurality of through electrodes, wherein the first conductive bumps are disposed on the second bonding pads, respectively, wherein the interposer is mounted on the package substrate via the first conductive bumps; first and second semiconductor devices provided on the interposer and spaced apart from each other, wherein front surfaces of each of the first and second semiconductor devices, on which chip pads are disposed, face the interposer, and wherein the first and second semiconductor devices are mounted on the interposer via second conductive bumps that are disposed on the chip pads, respectively; a sealing member disposed on the interposer and covering the first and second semiconductor devices; and an underfill member filling a space between the first conductive bumps that are between the package substrate and the interposer, wherein the interposer includes a central region and a peripheral region adjacent to the central region, and wherein the first conductive bumps include: first bump structures disposed in the central region and having a circular shape; and second bump structures disposed in the peripheral region and having an elliptical shape.

According to an example embodiment of the present inventive concept, a semiconductor package includes: a package substrate; an interposer mounted on the package substrate via first conductive bumps; first and second semiconductor devices disposed spaced apart from each other on the interposer and mounted on the interposer via second conductive bumps; and an underfill member filling a space between the first conductive bumps that are disposed between the package substrate and the interposer, wherein the interposer includes a central region and a peripheral region at least partially surrounding the central region, and wherein the first conductive bumps include: first bump structures disposed on second bonding pads, which are in the central region and on a lower surface of the interposer, respectively, and having a circular shape; and second bump structures disposed on second bonding pads, which are in the peripheral region and on the lower surface of the interposer, respectively, and having an elliptical shape.

According to an example embodiment of the present inventive concept, a semiconductor package includes: a package substrate; an interposer disposed on the package substrate, wherein the interposer includes a substrate, a wiring layer, first bonding pads, and second bonding pads, wherein the wiring layer is disposed on a first surface of the substrate and has a plurality of wirings, wherein the first bonding pads are disposed on the wiring layer and are electrically connected to the plurality of wirings, and wherein second bonding pads provided on a lower surface of the substrate; first and second semiconductor devices arranged on the interposer and spaced apart from each other; a plurality of first conductive bumps interposed between substrate pads of the package substrate and the second bonding pads of the interposer; and a plurality of second conductive bumps interposed between the first bonding pads of the interposer and chip pads of the first and second semiconductor devices, wherein the interposer includes a central region and a peripheral region at least partially surrounding the central region, and wherein the plurality of first conductive bumps include: first bump structures respectively disposed on the second bonding pads in the central region of the interposer and having a circular shape; and second bump structures respectively disposed on the second bonding pads in the peripheral region of the interposer and having an elliptical shape.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating a semiconductor package in accordance with an example embodiment of the present inventive concept.

FIG. 2 is a plan view illustrating the semiconductor package in FIG. 1.

FIG. 3 is an enlarged cross-sectional view illustrating portion ‘A’ in FIG. 1.

FIG. 4 is a plan view illustrating a lower surface of an interposer in FIG. 1.

FIG. 5 is an enlarged plan view illustrating portion ‘C’ in FIG. 4.

FIG. 6 is a perspective view of FIG. 5.

FIGS. 7, 8, 9, 10, 11, 12, 13, 14, 15, 16, 17, 18, 19, 20, 21, 22, 23, 24, 25, 26, 27, 28, 29, 30, and 31 are views illustrating a method of manufacturing a semiconductor package in accordance with an example embodiment of the present inventive concept.

### DETAILED DESCRIPTION OF THE EMBODIMENTS

Hereinafter, example embodiments of the present inventive concept will be explained in detail with reference to the accompanying drawings.

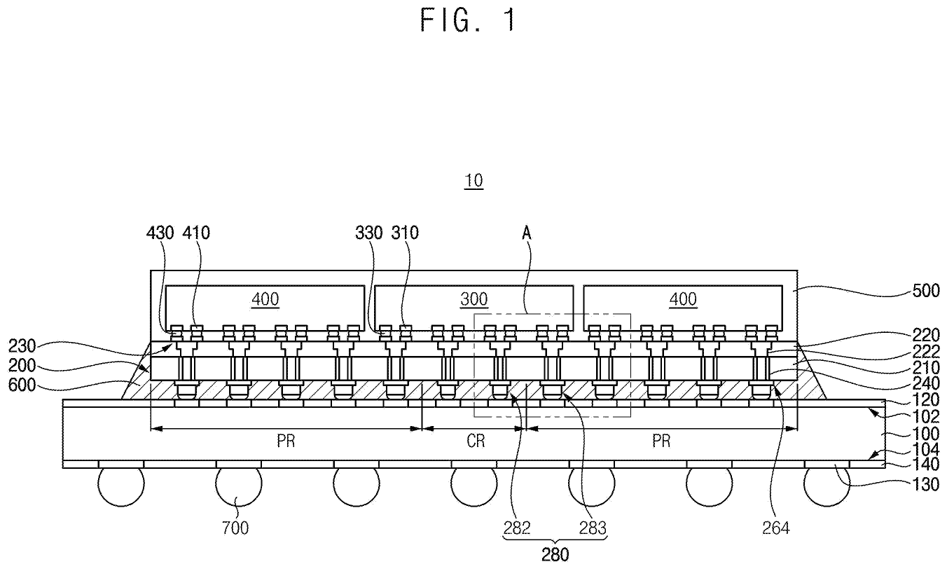

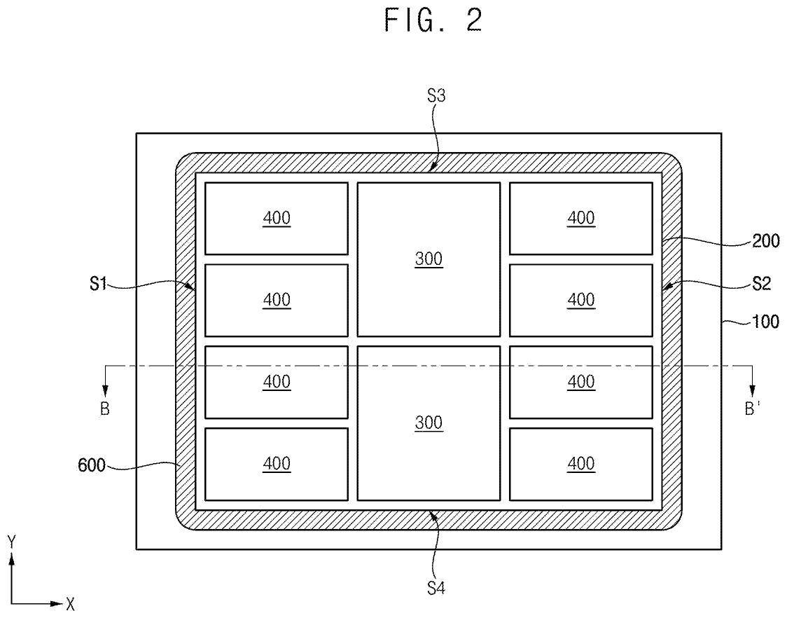

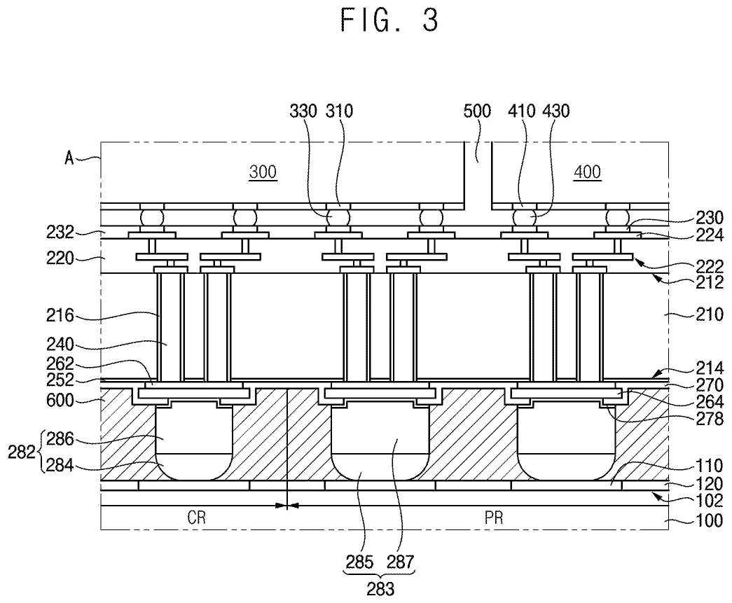

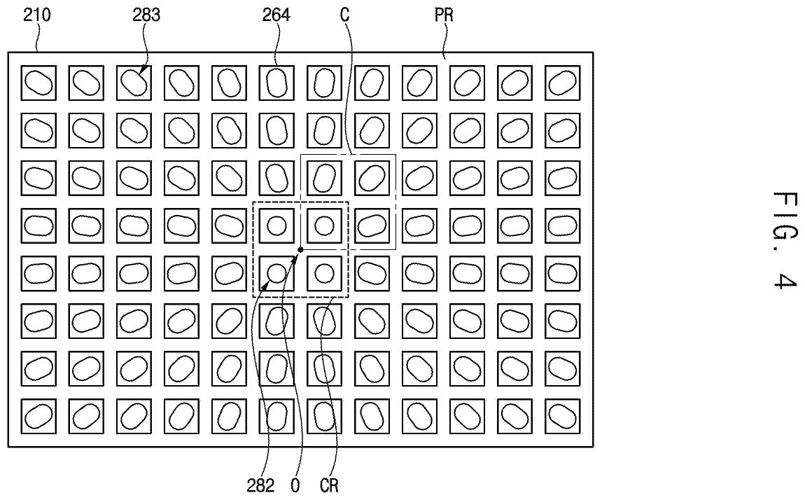

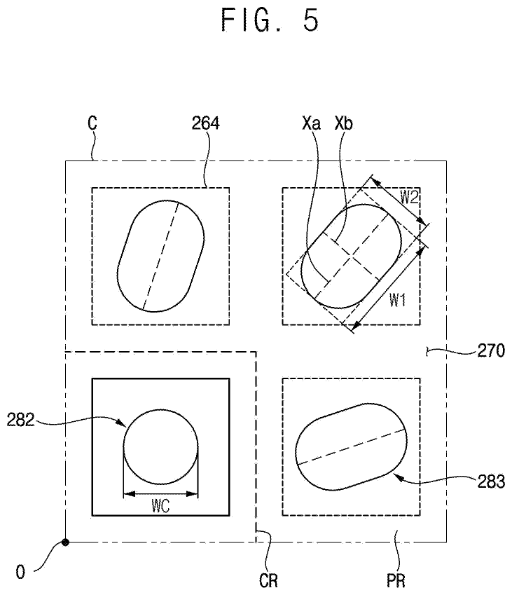

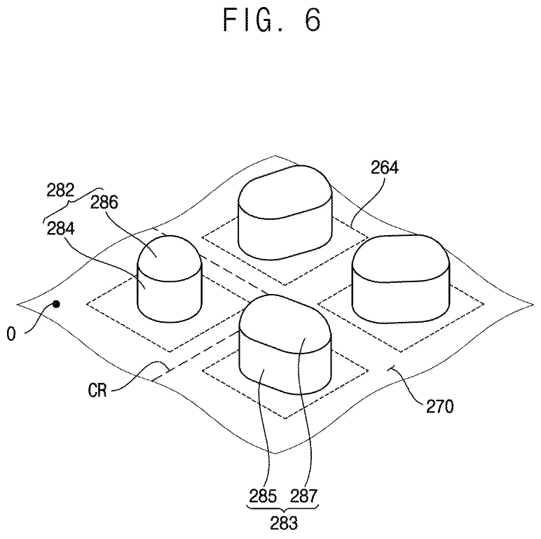

FIG. 1 is a cross-sectional view illustrating a semiconductor package in accordance with an example embodiment of the present inventive concept. FIG. 2 is a plan view illustrating the semiconductor package in FIG. 1. FIG. 3 is an enlarged cross-sectional view illustrating portion ‘A’ in FIG. 1. FIG. 4 is a plan view illustrating a lower surface of an interposer in FIG. 1. FIG. 5 is an enlarged plan view illustrating portion ‘C’ in FIG. 4. FIG. 6 is a perspective view of FIG. 5. FIG. 1 is a cross-sectional view taken along the line B-B′ in FIG. 2. FIG. 2 is a plan view illustrating the interposer in FIG. 1 wherein a sealing member on the interposer is omitted.

Referring to FIGS. 1 to 6, a semiconductor package 10 may include a package substrate 100, an interposer 200, a first semiconductor device 300, second semiconductor devices 400, a sealing member 500 and an underfill member 600.

In an example embodiment of the present inventive concept, the semiconductor package 10 may be a memory device having a stacked chip structure in which a plurality of dies (chips) are stacked. For example, the semiconductor package 10 may include a semiconductor memory device having a 2.5D chip structure. 2.5D refers to a packaging methodology in which a plurality of dies (chips) are integrated into a single package by assembling at least some of them side-by-side on a shared base (e.g., an interposer). The interposer may contain circuitry to electrically connect the plurality of dies (chips) to each other and to devices external to the package. In this case, the first semiconductor device 300 may include a logic semiconductor device, and the second semiconductor device 400 may include a memory device. The logic semiconductor device may be an ASIC used as a host such as a CPU, GPU, or SOC. The memory device may include a high bandwidth memory (HBM) device.

In an example embodiment of the present inventive concept, the package substrate 100 may be a substrate having an upper surface 102 and a lower surface 104 opposite to each other. For example, the package substrate 100 may be a printed circuit board (PCB). The PCB may be a multilayer circuit board having vias and various circuits therein.

The interposer 200 may be disposed on the package substrate 100. The interposer 200 may be mounted on the package substrate 100 via first conductive bumps 280. For example, a planar area of the interposer 200 may be less than a planar area of the package substrate 100; however, the present inventive concept is not limited thereto. When viewed in plan view, the interposer 200 may be disposed within the area of the package substrate 100. The interposer 200 may include a central region CR and a peripheral region PR at least partially surrounding the central region CR.

For example, the interposer 200 may have an area of about 5 mm×6 mm or more. A length of one side of the interposer 200 may be within a range of about 5 mm to about 90 mm. A length of one side of the central region CR may be within a range of about 200 μm to about 7,000 μm.

As illustrated in FIG. 2, the interposer 200 may include a first side surface S1, a second side surface S2, a third side surface S3, and a fourth side surface S4. The first side surface S1 and the second side surface S2 may extend in a direction parallel with a first direction (Y direction), which is parallel to the upper surface thereof, and the first side surface S1 and the second side surface S2 are opposite to each other. The third side surface S3 and the fourth side surface S4 extend in a direction parallel with a second direction (X direction), which is substantially perpendicular to the first direction, and the third side surface S3 and the fourth side surface S4 are opposite to each other. The interposer 200 may have a polygonal shape such as a rectangular shape.

The two first semiconductor devices 300 may be arranged in a middle region of the interposer 200. The two first semiconductor devices 300 may be spaced apart from each other along the first direction (Y direction). The second semiconductor devices 400 may be arranged adjacent to each other on two sides of the first semiconductor device 300. The two second semiconductor devices 400 may be arranged along the first side surface S1 facing a first side of the first semiconductor device 300 and may be spaced apart from each other, and the two second semiconductor devices 400 may be arranged along the second side surface S2 facing a second side, opposite to the first side, of the first semiconductor device 300 and may be spaced apart from each other.

The interposer 200 may be a silicon interposer or a redistribution interposer having a plurality of wirings therein. The first semiconductor device 300 and the second semiconductor devices 400 may be connected to each other through the wirings inside the interposer 200 and/or electrically connected to the package substrate 10 through the first conductive bumps 280. The interposer 200 may provide a high density interconnection between the first and second semiconductor devices 300 and 400.

As illustrated in FIG. 3, the interposer 200 may include a substrate 210, a wiring layer 220, a plurality of first bonding pads 230, and a plurality of second bonding pads 264. The wiring layer 220 has a plurality of wirings 222 disposed on an upper surface, that is, a first surface 212 of the substrate 210. The plurality of first bonding pads 230 may be provided on the wiring layer 220, and the plurality of second bonding pads 264 may be provided on a lower surface, that is, the second surface 214 of the substrate 210.

The substrate 210 may include a semiconductor material such as silicon, germanium, or silicon-germanium, or III-V compounds, e.g., gallium phosphide (GaP), gallium arsenide (GaAs), gallium antimonide (GaSb), etc.

The wiring layer 220 may include a plurality of insulating layers and a plurality of wirings 222 disposed in the insulating layers. For example, the wirings may include a metal such as copper (Cu) or aluminum (Al).

The substrate 210 may include a plurality of through electrodes 240 formed to penetrate therethrough. The through electrode 240 may include a through silicon via (TSV). The through electrode 240 may be provided to extend in a thickness direction from (e.g., a direction substantially perpendicular to) the first surface 212 of the substrate 210. One end portion of the through electrode 240 may contact the wiring 222 of the wiring layer 220. Accordingly, the wiring 222 may be electrically connected to the through electrode 240.

The first bonding pads 230 may be formed on the wiring layer 220 and may be electrically connected to the wirings 222. The first bonding pad 230 may be formed on a first redistribution pad 224, which may be an uppermost wiring of the wirings 220. A first protective layer pattern 232 may be formed on the wiring layer 220 to cover the first redistribution pads 224 and expose at least portions of the first bonding pads 230. For example, the first bonding pad 230 may include copper (Cu), aluminum (Al), tungsten, nickel (Ni), molybdenum (Mo), gold (Au), silver (Ag), or chromium (Cr), tin (Sn), titanium (Ti), etc. For example, the first bonding pad 230 may have a diameter within a range of about 5 μm to about 40 μm.

The first protective layer pattern 232 may be formed on the wiring layer 220 and may cover the first redistribution pads 224 and expose at least portions of the first bonding pads 230. The first protective layer pattern 232 may include a passivation layer including a nitride such as silicon nitride (SiN).

The second bonding pads 264 may be disposed on end portions of the through electrodes 240 that are exposed from the second surface 214 of the substrate 210. The second bonding pad 264 may be electrically connected to the through electrode 240. For example, one second bonding pad 264 may be electrically connected to two adjacent through electrodes 240. For example, the second bonding pad 264 may have a polygonal shape, such as rectangular shape. A length of one side of the second bonding pad 264 may be greater than the diameter of the first bonding pad 230. For example, the length of one side of the second bonding pad 264 may be within a range of about 25 μm to about 200 μm.

A second protective layer pattern 270 may be provided on an insulating layer pattern 252 that is on the second surface 214 of the substrate 210 and may expose at least portions of the second bonding pads 264. For example, the second protective layer pattern 270 may include an insulating material such as Photo Imagable Dielectrics (PID).

The number, size, arrangement, etc. of the through electrodes 240, the insulating layers of the wiring layer, the wirings 222, the first redistribution pads 224, the first bonding pads 230, and the second bonding pads 264 are provided as examples, and it will be understood that the present inventive concept is not limited thereto.

In an example embodiment of the present inventive concept, the interposer 200 may be mounted on the package substrate 100 via first conductive bumps 280 as conductive connecting members. The first conductive bumps 280 may be respectively disposed on the second bonding pads 264. The second bonding pad 264 of the interposer 200 may be electrically connected to a substrate pad 110 of the package substrate 100 by the first conductive bump 280.

As illustrated in FIGS. 3 to 6, the first conductive bumps 280 may include first bump structures 282 and second bump structures 283. The first bump structures 282 may be respectively disposed on the second bonding pads 264 in the central region CR and may have a circular shape when viewed in plan view. The second bump structures 283 may be respectively disposed on the second bonding pads 264 in the peripheral region PR and may have an elliptical shape when viewed in plan view.

The first bump structure 282 may include a first pillar bump 284 and a first solder bump 286. The first pillar bump 284 may have a cylindrical shape. The first solder bump 286 may have a hemispherical shape and may be formed on the first pillar pump 284. The second bump structure 283 may include a second pillar bump 285 and a second solder bump 287. The second pillar bump 285 may have an elliptical column shape. The second solder bump 287 may have a semi-ellipsoidal shape and may be formed on the second pillar bump 285.

For example, the first and second pillar pumps 284 and 285 may have a single layer structure. The first and second pillar pumps 284 and 285 may include a plating pattern layer including, for example, copper (Cu). The first and second solder bumps 286 and 287 may include solder.

In addition, the first and second pillar pumps 284 and 285 may have a multilayer structure. In this case, the first and second pillar pumps 284 and 285 may include sequentially stacked first to third plating pattern layers. For example, the first and third plating pattern layers may include copper (Cu), and the second plating pattern layer may include nickel (Ni). A thickness H of the first and second bump structures 282 and 283 may be within a range of about 10 μm to about 80 μm.

As illustrated in FIGS. 4 and 5, the second bump structures 283 may be arranged such that long axes Xa of the second bump structures 283 extends toward the center O of the interposer 200. When viewed in plan view, the first bump structure 282 may have a circular shape, and the second bump structure 283 may have an elliptical shape having a long axis (major axis) Xa and a short axis (minor axis) Xb. The first bump structure 282 may have a diameter Wc within a range of about 20 μm to about 180 μm. The long axis (major axis) Xa of the second bump structure 283 may have a length W1 within a range of about 25 μm to about 200 μm, and the short axis (minor axis) Xb of the second bump structure 283 may have a length W2 within a range of about 20 μm to about 180 μm.

In an example embodiment of the present inventive concept, the first semiconductor device 300 may be disposed on the interposer 200. The first semiconductor device 300 may be mounted on the interposer 200 by a flip chip bonding method. In this case, the first semiconductor device 300 may be arranged on the interposer 200 such that an active surface, of the first semiconductor device 300, on which chip pads 310 are formed faces the interposer 200. The chip pads 310 of the first semiconductor device 300 may be electrically connected to the first bonding pads 230 of the interposer 200 by second conductive bumps 330. For example, the second conductive bumps 330 may include micro bumps (uBumps).

The second semiconductor devices 400 may be disposed on the interposer 200 and may be spaced apart from the first semiconductor device 300. The second semiconductor devices 400 may be mounted on the interposer 200 by a flip chip bonding method. In this case, the second semiconductor device 400 may be arranged on the interposer 200 such that an active surface, on the second semiconductor device 400, on which chip pads 410 are formed faces the interposer 200. The chip pads 410 of the second semiconductor device 400 may be electrically connected to the first bonding pads 230 of the interposer 200 by second conductive bumps 430. For example, the second conductive bumps 430 may include micro bumps (uBumps).

Although two first semiconductor devices 30) and eight second semiconductor devices 400 are illustrated to be disposed, it will be understood that the present inventive concept is not limited thereto. For example, the second semiconductor device 400 may include a buffer die and a plurality of memory dies (e.g., chips) sequentially stacked on the buffer die. The buffer die and the memory die may be electrically connected to each other by through silicon vias (TSVs).

The wirings 222 may be electrically connected to the through electrodes 240. The first and second semiconductor devices 300 and 400 may be electrically connected to the package substrate 100 through the wirings 222 and the through electrodes 240. The first semiconductor device 300 and the second semiconductor device 400 may be electrically connected to each other through the wirings 222.

In an example embodiment of the present inventive concept, the sealing member 500 may cover the first and second semiconductor devices 300 and 400 and may be disposed on the interposer 200. The sealing member 500 may cover side surfaces of the first and second semiconductor devices 300 and 400.

Upper surfaces of the first and second semiconductor devices 300 and 400 may be covered by the sealing member 500. In addition, the upper surfaces of the first and second semiconductor devices 300 and 400 may be exposed by the sealing member 500. In this case, an upper surface of the sealing member 500 may be positioned to be substantially coplanar with the upper surfaces of the first and second semiconductor devices 300 and 400.

In an example embodiment of the present inventive concept, the underfill member 600 may be underfilled between the first semiconductor device 300 and the interposer 200 to fill a space between the first conductive bumps 280.

The underfill member 600 may include a material having relatively high fluidity to effectively fill a small space between the interposer 200 and the package substrate 100. For example, the underfill member 600 may include an adhesive including an epoxy material.

Second underfill members may be underfilled between the first semiconductor device 300 and the interposer 200 and between the second semiconductor device 400 and the interposer 200. The second underfill member may be substantially the same as the first underfill member.

External connection pads 130 may be formed on a lower surface of the package substrate 100, and external connection members 700 for electrical connection with an external device may be disposed on the external connection pads 130. For example, the external connection member 700 may be a solder ball. The semiconductor package 10 may be mounted on a module substrate via the solder balls to form a memory module.

As mentioned above, the semiconductor package 10 may include the interposer 200 mounted on the package substrate 100 via the first conductive bumps 280. Further, the semiconductor package 10 may include the first and second semiconductor devices 300 and 400 that may be disposed on the interposer 200. The semiconductor package 10 may additionally include the underfill member 600 filling the space between the first conductive bumps 280 between the package substrate 100 and the interposer 200.

The interposer 200 may include the central region CR and the peripheral region PR surrounding the central region CR. The first conductive bumps 280 may include the first bump structures 282, which may be disposed in the central region CR and may have a circular shape when viewed in plan view, and the second bump structures 283, which may be disposed in the peripheral region PR and may have an elliptical shape when viewed in plan view.

The first bump structures 282 having the circular shape may be formed in the central region CR to increase the flowability of the underfill material in an underfill process for forming the underfill member 600, to thereby prevent void traps. Further, the second bump structures 283 having the elliptical shape may be disposed in the peripheral region PR of the interposer 200 to prevent misalignment during flip chip bonding of the interposer 200 to the package substrate 100.

Hereinafter, a method of manufacturing the semiconductor package of FIG. 1 will be described.

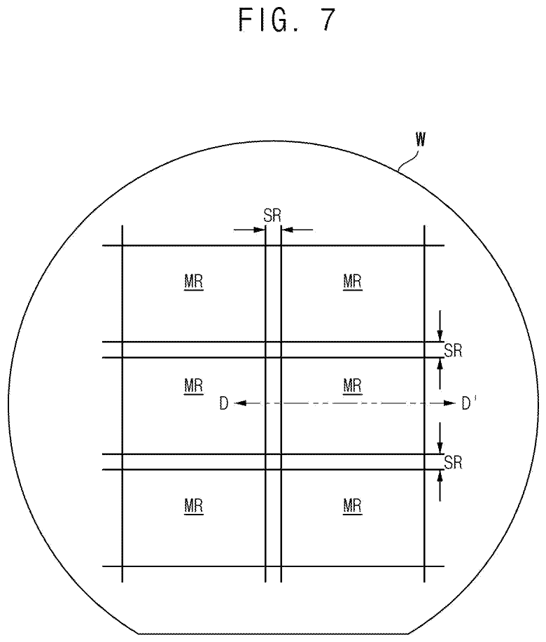

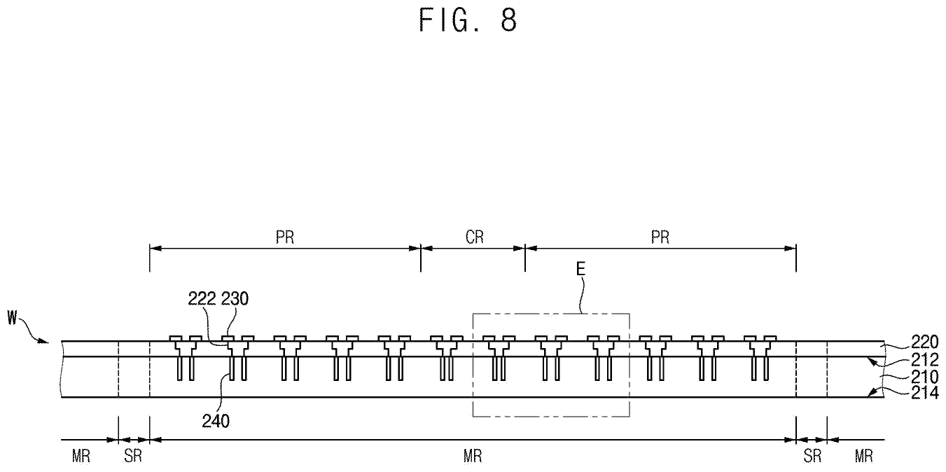

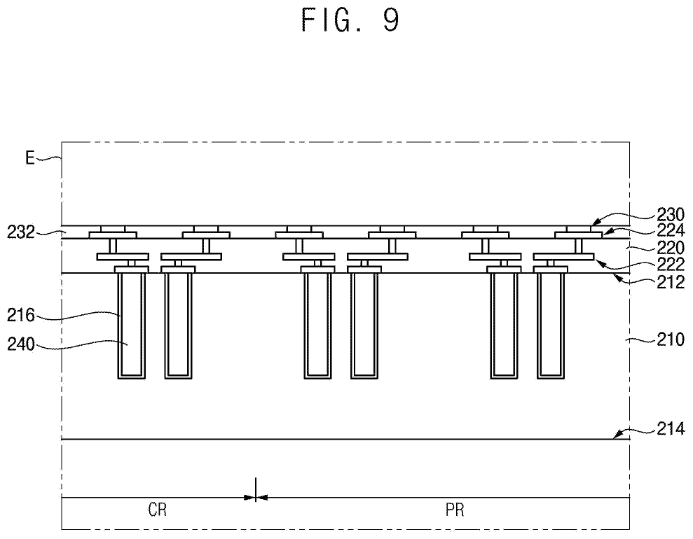

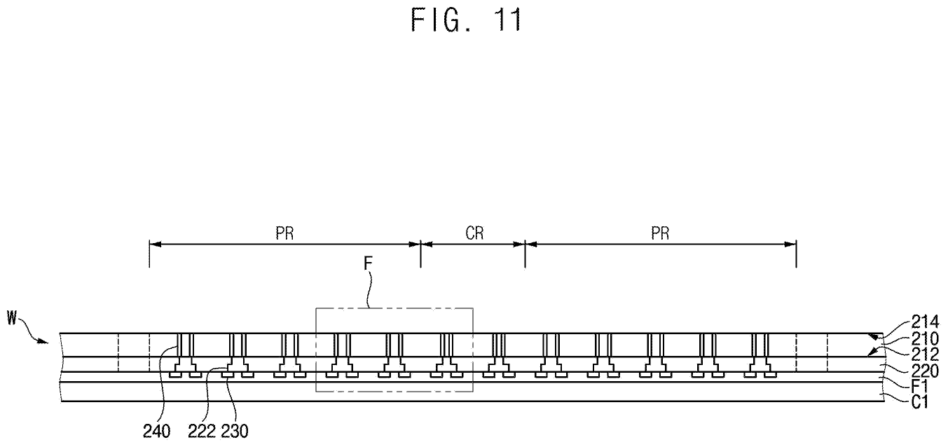

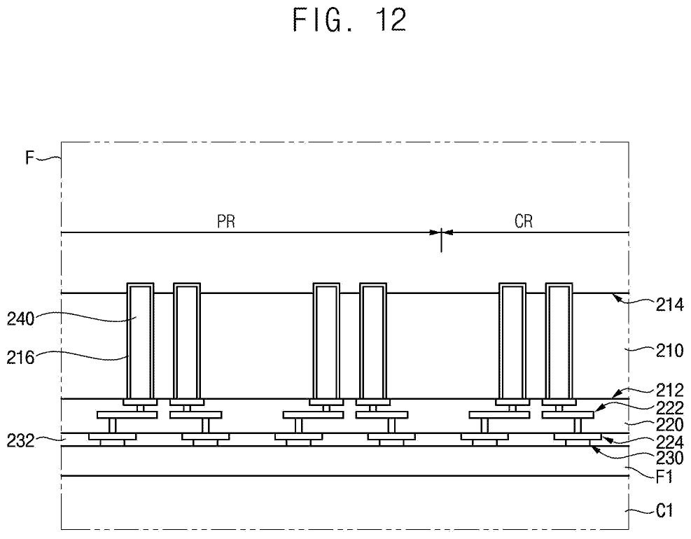

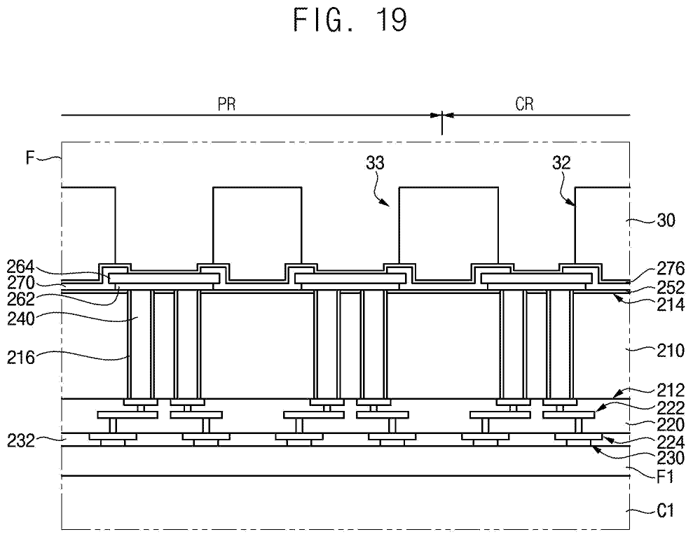

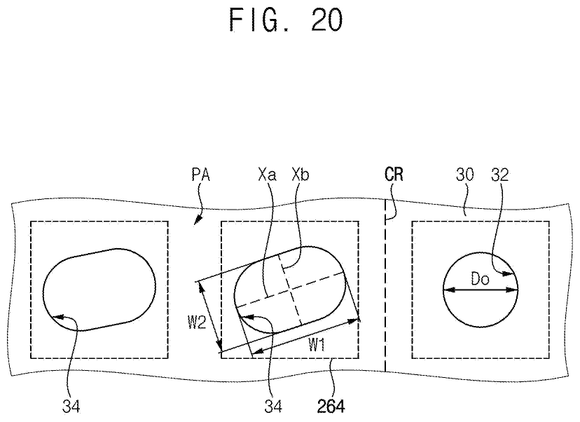

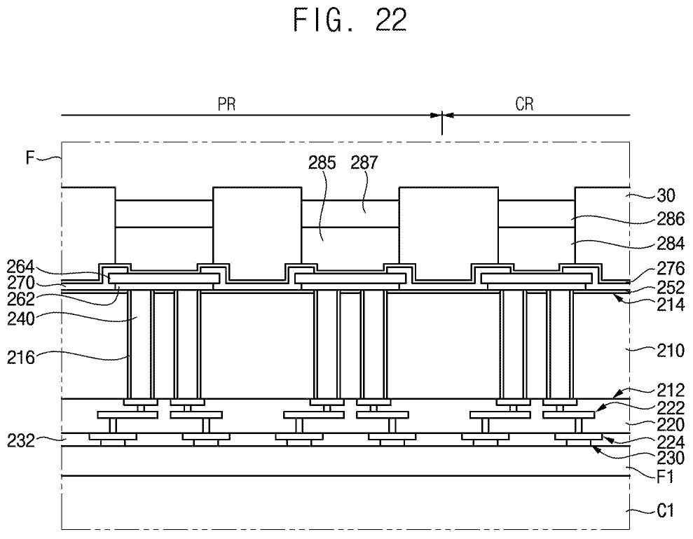

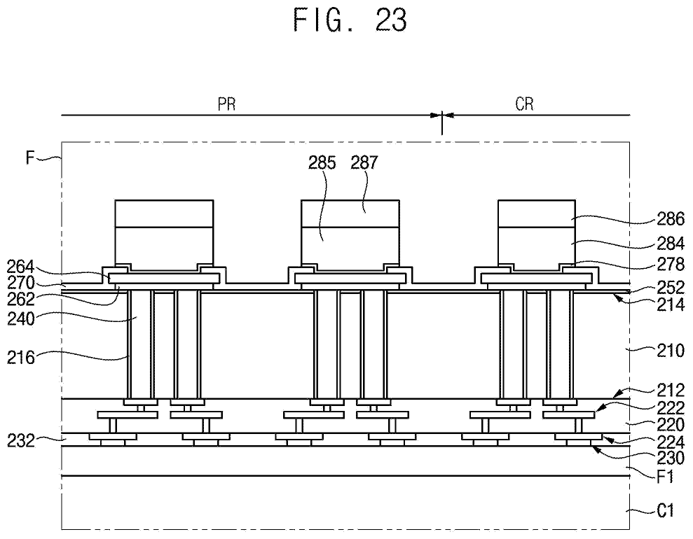

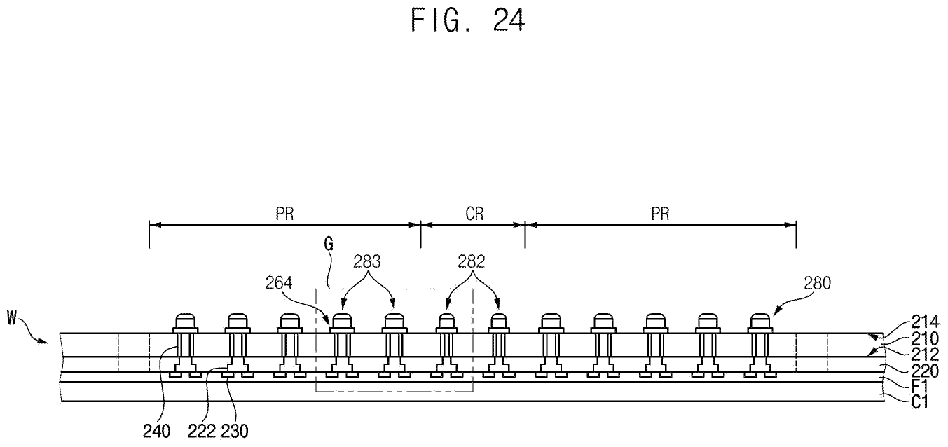

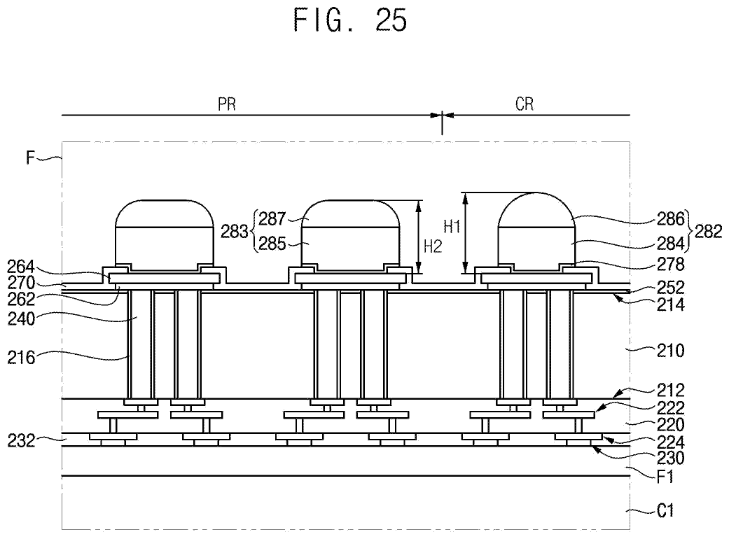

FIGS. 7 to 31 are views illustrating a method of manufacturing a semiconductor package in accordance with an example embodiment of the present inventive concept. FIG. 8 is a cross-sectional view taken along the line D-D′ in FIG. 7. FIG. 9 is an enlarged cross-sectional view illustrating portion ‘E’ in FIG. 8. FIGS. 12 to 19 and FIGS. 21 to 23 are enlarged cross-sectional views illustrating portion ‘F’ in FIG. 11. FIG. 20 is a plan view illustrating a second photoresist pattern in FIG. 19. FIG. 25 is an enlarged cross-sectional view illustrating ‘G’ in FIG. 24.

Referring to FIGS. 7 to 9, first, a semiconductor wafer W for a silicon interposer may be provided.

In an example embodiment of the present inventive concept, the wafer W may include a substrate 210 and a wiring layer 220. The substrate 210 may have a first surface 212 and a second surface 214 opposite the first surface 212. The wiring layer 220 may be provided on the first surface 212 of the substrate 210.

The wafer W may include a package region, that is, a mounting region MR where semiconductor device(s) are mounted and a scribe lane region, that is, a cutting region SR surrounding the mounting region MR. The mounting region MR may include a central region CR and a peripheral region PR surrounding the central region CR. As described later, the wafer W may be cut along the cutting region SR that divides the mounting region MR to form an individual interposer. For example, the mounting region MR may have an area of about 5 mm×6 mm or more. A length of one side of the mounting region MR may be within a range of about 5 mm to about 90 mm. A length of one side of the central region CR may be within a range of about 200 μm to about 7,000 μm.

For example, the substrate 210 may include a semiconductor material such as silicon, germanium, silicon-germanium, or a group III-V compound semiconductor such as gallium phosphide (GaP), gallium arsenide (GaAs), or gallium antimonide (GaSb). In some example embodiments of the present inventive concept, the substrate 210 may be a silicon-on-insulator (SOI) substrate or a germanium-on-insulator (GOI) substrate.

The substrate 210 may include a plurality of through electrodes (e.g., through silicon vias) 240 formed therein. The through electrodes 240 may be electrically connected to wirings 222, respectively. The through electrode 240 may be formed before grinding a backside surface of the substrate 210, that is, the second surface 214. In addition, the through electrode may be formed after grinding the backside surface of the substrate 210 as illustrated in FIG. 11.

For example, a via hole may be formed to extend from the first surface 212 of the substrate 210 by a predetermined depth, and an insulating layer 216 may be formed along a profile of a sidewall and a bottom surface of the via hole and the first surface 212 of the substrate 210. For example, the depth of the via hole may be within a range of about 10 μm to about 120 μm.

Then, after a barrier metal layer and a seed layer are sequentially formed on the insulating layer 216, a conductive layer may be formed on the seed layer. The barrier metal film may be formed of materials such as Ta, TaN, Ti, TiN, Ru, Co, Ni, NiB, WN, and the like, and these may be used alone or a mixture thereof. The seed layer may be formed by depositing copper through a physical vapor deposition process.

Then, the conductive layer may be formed on the seed layer to fill the via hole. For example, the conductive layer may be formed by depositing copper by an electrolytic plating process, an electroless plating process, an electrografting process, a physical vapor deposition process, or the like. The conductive layer, the barrier metal layer and the insulating layer may be polished by a chemical mechanical polishing process to form the through electrode 240.

The wiring layer 220 may be formed on the first surface 212 of the substrate 210. The wiring layer 220 may be formed by a back process referred to as BEOL (Back End of Line) process. The wiring layer 220 may include a plurality of insulating layers and a plurality of wirings 222 in the insulating layers. For example, the wirings 222 may include a metal such as copper (Cu) or aluminum (Al). Some of the wirings 222 may be formed on the through electrode 240. Accordingly, the wiring 222 may be electrically connected to the through electrode 240.

First bonding pads 230 may be formed on the wiring layer 220 and may be electrically connected to the wirings 222. The first bonding pad 230 may be formed on a first redistribution pad 224 as an uppermost wiring of the wirings 222. A first protective layer pattern 232 may be formed on the wiring layer 220 to cover the first redistribution pads 224 and expose at least portions of the first bonding pads 230.

For example, a first passivation layer may be formed on the wiring layer 220, and the first passivation layer may be patterned to expose at least portions of the first redistribution pads 224. Further, the first bonding pads 230 may be formed on the exposed portions of the first redistribution pads 224. The first bonding pads 230 may be simultaneously formed by a plating process. For example, the first bonding pad 230 may include copper (Cu), aluminum (Al), tungsten, nickel (Ni), molybdenum (Mo), gold (Au), silver (Ag), chromium (Cr), tin (Sn), titanium (Ti), etc. The first bonding pad 230 may have a diameter within a range of about 5 μm to about 40 μm.

A plating layer may be formed on the first bonding pad 230. The plating layer may include a metal different from that of the first bonding pad 230.

For example, the insulating layers may be formed to include an oxide such as silicon oxide, carbon-doped oxide, or fluorine-doped oxide. The first passivation layer may include a passivation layer including a nitride such as silicon nitride (SiN). In addition, the first passivation layer may include an organic passivation layer, which may include an oxide layer, and an inorganic passivation layer, which may include a nitride layer and may be stacked on the organic passivation layer. The wirings 222 and the redistribution pads may include a metal material such as aluminum (Al) or copper (Cu).

The number, size, arrangement, etc. of the insulating layers, the wirings 222, the first redistribution pads 224, and the first bonding pads 230 of the wiring layer 220 are provided as examples, and it will be understood that the present inventive concept is not limited thereto.

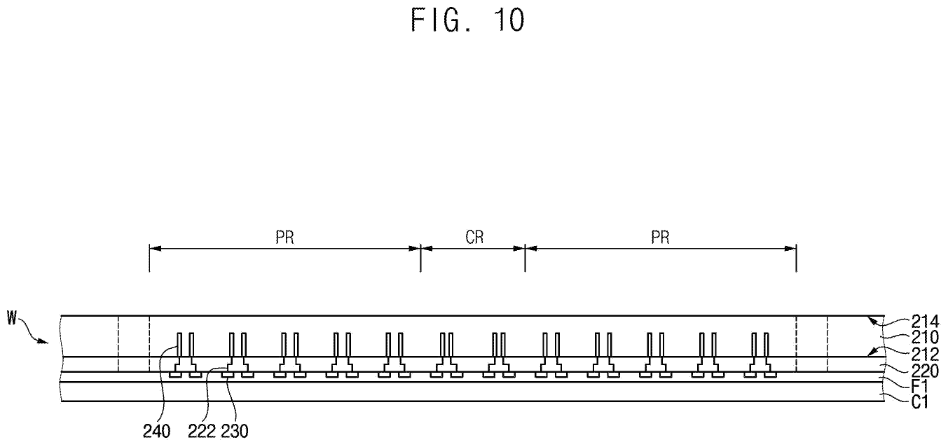

Referring to FIGS. 10 to 25, second bonding pads 264 may be formed on the second surface 214 of the substrate 210, and conductive bumps 280 as conductive connection members may be formed on the second bonding pads 264.

As illustrated in FIGS. 10 to 12, the backside surface of the substrate 210, that is, the second surface 214 may be polished using a substrate support system (WSS). The wafer W may be adhered on a first carrier substrate C1 using a first adhesive film F1, and the second surface 214 of the substrate 210 may be grinded until portions of the through electrodes 240 are exposed.

The second surface 214 of the substrate 210 may be partially removed by a grinding process such as a chemical mechanical polishing (CMP) process. Thus, a thickness of the substrate 210 may be reduced to a desired thickness. For example, the substrate 210 may have a thickness ranging from about 40 μm to about 150 μm. Then, a silicon recess etching process may be performed on the second surface 214 of the substrate 210 to expose one end portion of the through electrode 240 from the second surface 214 of the substrate 210.

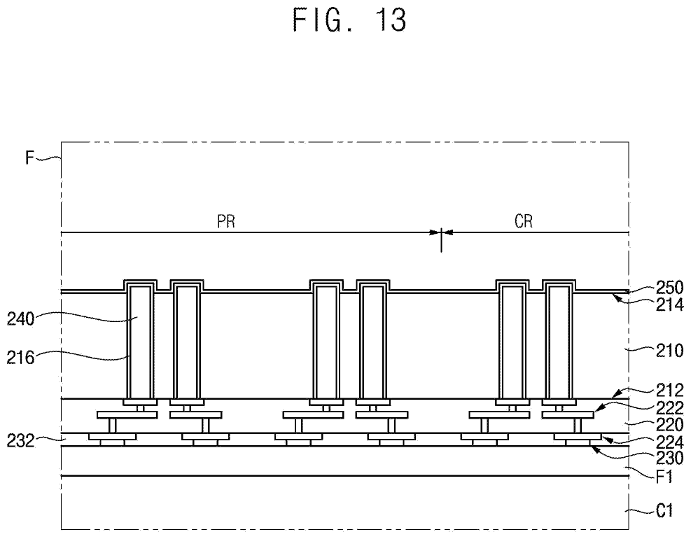

As illustrated in FIG. 13, an insulating layer 250 may be formed on the second surface 214 of the substrate 210. The one end portion of the through electrode 240 protruding from the second surface 214 of the substrate 210 may be covered by the insulating layer 250. For example, the insulating layer 250 may be formed by a chemical vapor deposition (CVD) process.

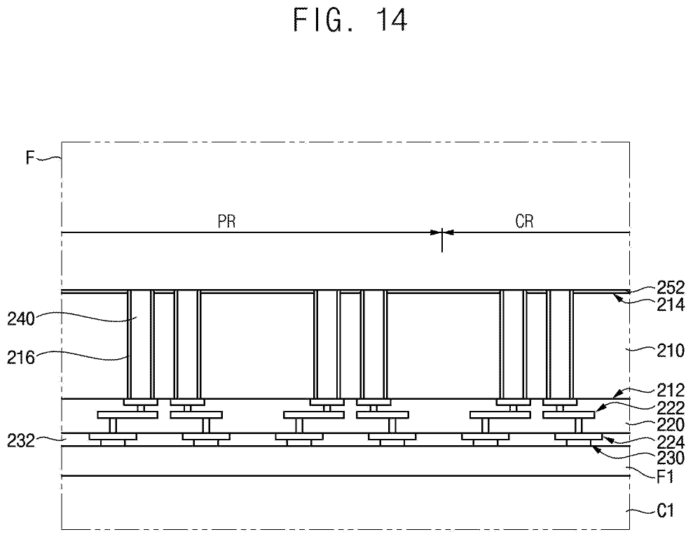

As illustrated in FIG. 14, the one end portion of the through electrode 240 protruding from the second surface 214 of the substrate 210 may be removed. At this time, a portion of the insulating layer 250 on the protruding one end portion of the through electrode 240 may be removed together to form an insulating layer pattern 252 that exposes one end portion of the through electrode 240. The one end portion of the protruding through electrode 240 may be partially removed by a grinding process such as a chemical mechanical polishing (CMP) process.

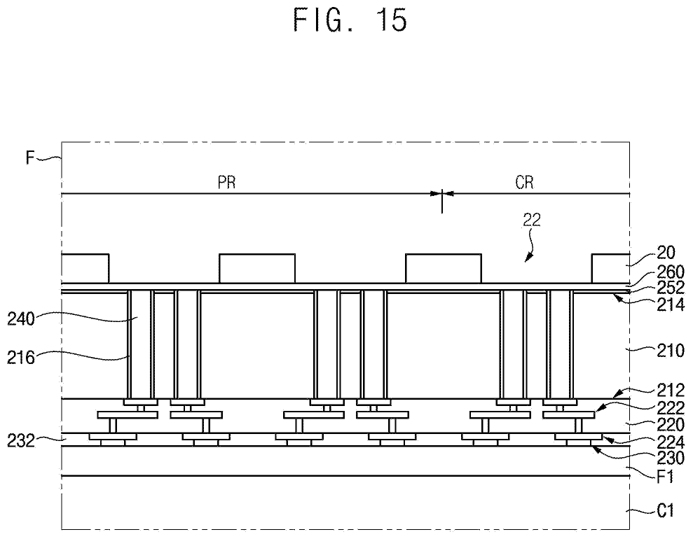

As illustrated in FIG. 15, a seed layer 260 may be formed on the insulating layer pattern 252, which is on the second surface 214 of the substrate 210, and the exposed one end portion of the through electrode 240, and a first photoresist pattern 20 having a first opening 22 that exposes a second bonding pad region may be formed on the seed layer 260. One first opening 22 of the first photoresist pattern 20 may simultaneously expose end portions of two adjacent through electrodes 240.

For example, the seed layer may be formed by a deposition process. The seed layer may include, for example, nickel (Ni), copper (Cu), titanium (Ti), tantalum (Ta), etc. A photoresist layer may be formed on the seed layer 260, and an exposure process may be performed to form the first photoresist pattern 20 having the first openings 22 that exposes the portions of the seed layer 260.

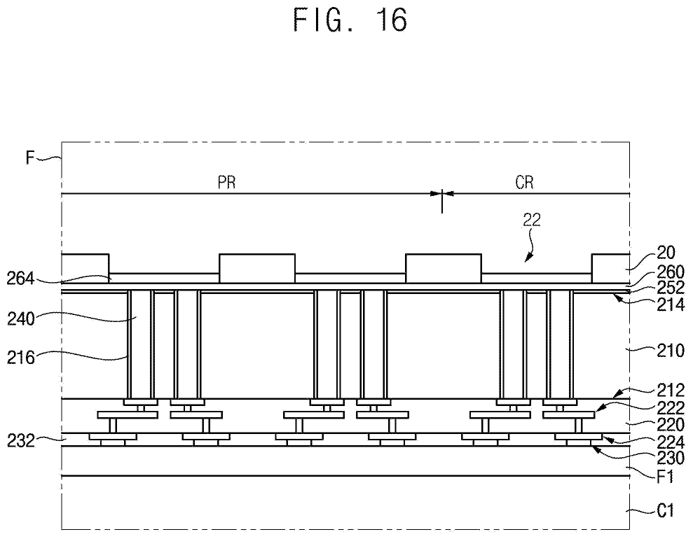

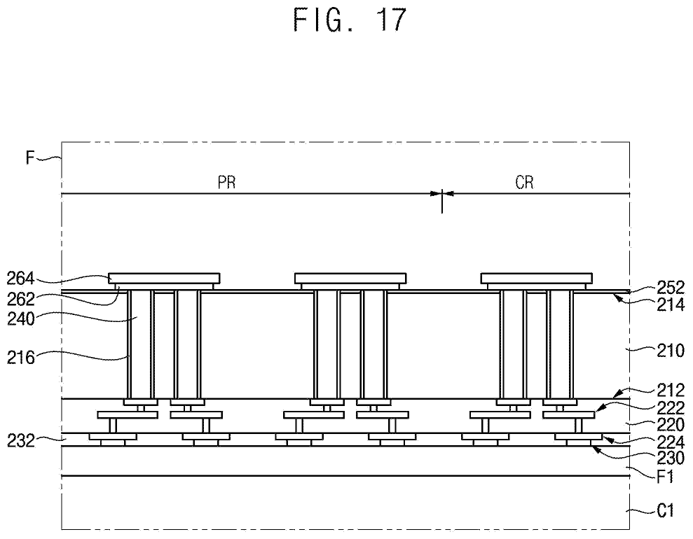

As illustrated in FIGS. 16 and 17, the first openings 22 of the first photoresist pattern 20 may be filled up with a conductive material to form the second bonding pads 264 The first photoresist pattern 20 may be removed from the wafer W, and portions of the seed layer 260 exposed by the second bonding pads 264 may be removed to form a seed layer pattern 262.

The second bonding pad 264 may be formed by a plating process. The second bonding pad 264 may be formed on the through electrode 240. The second bonding pad 264 may be electrically connected to the through electrode 240. For example, one second bonding pad 264 may be electrically connected to two adjacent through electrodes 240. The second bonding pad 264 may have a polygonal shape, such as a rectangular shape. A length of one side of the second bonding pad 264 may be within a range of about 25 μm to about 200 μm.

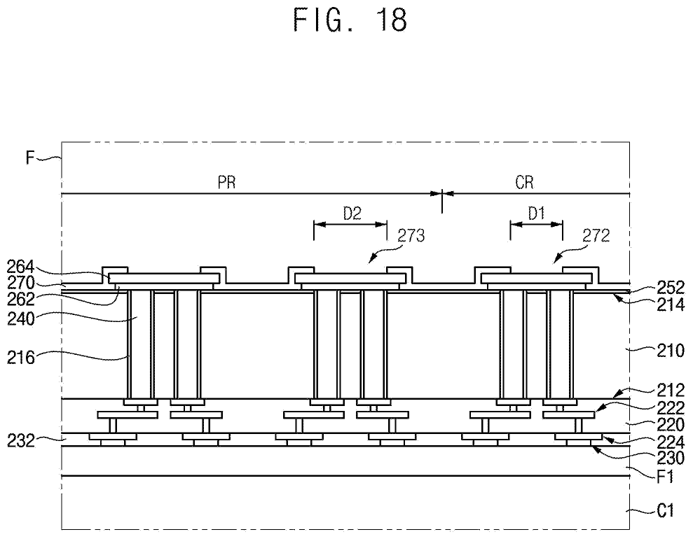

As illustrated in FIG. 18, a second protective layer pattern 270 may be formed on the insulating layer pattern 252 and may expose at least a portion of the second bonding pad 264. For example, the second protective layer pattern 270 may include an insulating material such as Photo Imagable Dielectrics (PID). A photosensitive insulating layer may be formed on the insulating layer pattern 252 to cover the second bonding pads 264, and the photosensitive insulating layer may be patterned by a photo process to form second openings 272 and 273 that expose the portions of the second bonding pads 264.

The second opening 272 formed in the central region CR may have a first diameter D1, and the second opening 273 formed in the peripheral region PR may have a second diameter D2 greater than the first diameter D1.

Referring to FIGS. 19 and 20, a seed layer 276 may be formed on the second protective layer pattern 270 and the exposed portions of the second bonding pads 264, and a second photoresist pattern 30 having a third opening 32 exposing a first bump structure region and a fourth opening 33 exposing a second bump structure region may be formed on the seed layer 276.

For example, when viewed in plan view, the third opening 32 formed in the central region CR may have a circular shape, and the fourth opening 33 formed in the peripheral region PR may have an elliptical shape. The fourth opening 33 may have an elliptical shape having a long axis (major axis) and a short axis (minor axis). The fourth openings 33 may be formed such that long axes Xa of the fourth openings 33 face the center of the mounting region MR. The third opening 32 may have a diameter DO within a range of about 20 μm to about 180 μm. The long axis Xa of the fourth opening 33 may have a length W1 within a range of about 25 μm to about 200 μm, and the short axis Xb of the fourth opening 33 may have a length W2 within a range of about 200 μm to about 180 μm.

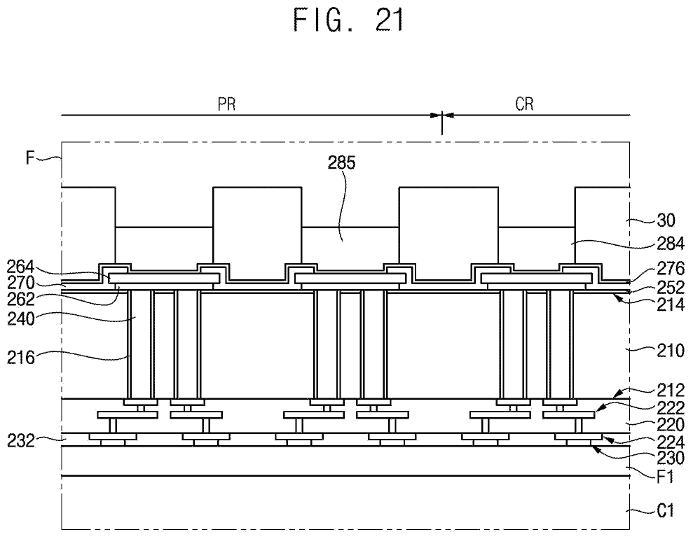

As illustrated in FIGS. 21 to 23, the third and fourth openings 32 and 33 of the second photoresist pattern 30 may be filled up with a conductive material to form bump structures, and the second photoresist pattern 30 may be removed from the wafer W. Further, portions of the seed layer 276 exposed by the bump structures may be removed to form a seed layer pattern 278.

For example, a first bump structure having a circular shape may be formed in the third opening 32 that is formed in the central region CR, and a second bump structure having an elliptic shape may be formed in the fourth opening 33 that is formed in the peripheral region PR. The first bump structure may include a first pillar bump 284, which has a circular shape, and a first solder bump 286, which is formed on the first pillar pump 284. The second bump structure may include a second pillar bump 285, which has an elliptical shape, and a second solder bump 287, which is formed on the second pillar bump 285.

For example, the first and second pillar pumps 284 and 285 may have a single layer structure. The first and second pillar pumps 284 and 285 may include a plating pattern layer including copper (Cu). The first and second solder bumps 286 and 287 may include solder.

In addition, the first and second pillar pumps 284 and 285 may have a multilayer structure. In this case, the first and second pillar pumps 284 and 285 may include sequentially stacked first to third plating pattern layers. For example, the first and third plating pattern layers may include copper (Cu), and the second plating pattern layer may include nickel (Ni).

As illustrated in FIGS. 24 and 25, a reflow process may be performed on the first and second solder bumps 284 and 285 to form the first conductive bumps 280 on the second bonding pads 264.

The first conductive bumps 280 may include first bump structures 282, which are respectively disposed on the second bonding pads 264 in the central region CR, and second bump structures 283, which are respectively disposed on the second bonding pads 264 in the peripheral region PR. The first bump structure 282 may have a first thickness H1, and the second bump structure 283 may have a second thickness H2 greater than or equal to the first thickness H1. The first and second thicknesses H1 and H2 of the first and second bump structures 282 and 283, respectively, may be within a range of about 10 μm to about 80 μm.

The first solder bumps 286, which is disposed on the circular shaped first pillar bump 284, may be formed by the reflow process to be higher than the second solder bumps 287 that is disposed on the oval shaped second pillar bump 285. Thus, when the interposer is mounted on a package substrate by a flip chip bonding method, the first solder bumps 286 may be bonded on the package substrate before the second solder bumps 287 to reduce misalignment.

When the thicknesses of the first and second pillar bumps 284 and 285 are relatively small, the first and second pillar bumps 284 and 285 may be referred to as second bonding pads, and the second bonding pads 264 may be referred to as second redistribution pads.

Then, the first carrier substrate C1 may be removed from the wafer W.

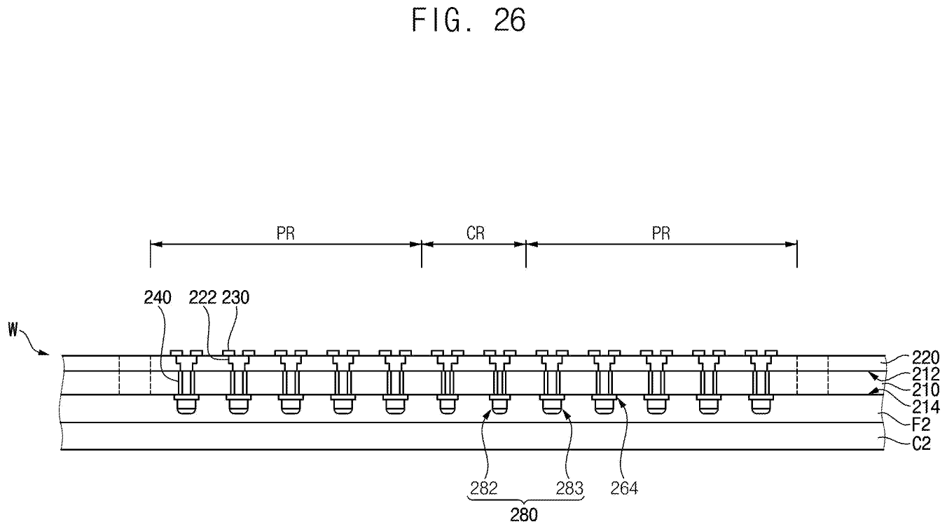

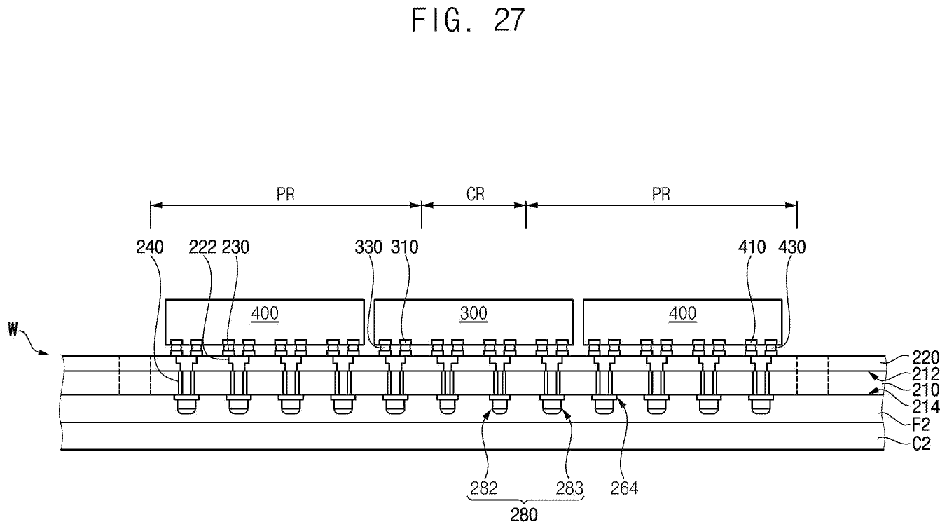

Referring to FIGS. 26 and 27, the structure of FIG. 24 may be turned over, and a first semiconductor device 300 and second semiconductor devices 400 may be mounted on the wiring layer 220 respectively. Then, an underfill member may be formed between the first semiconductor device 300 and the wiring layer 220, and an underfill member may be formed between the second semiconductor device 400 and the wiring layer 220.

As illustrated in FIG. 26, the wafer W may be adhered onto a second carrier substrate C2 using a second adhesive film F2. The wafer W may be adhered onto the second carrier substrate C2 such that the first bonding pads 230 face upwardly to be exposed.

As illustrated in FIG. 27, the first semiconductor device 300 and the second semiconductor devices 400 may be arranged on the wiring layer 220, and may be spaced apart from each other. The first semiconductor device 300 may be arranged in a middle region of the mounting region MR, and the second semiconductor devices 400 may be disposed on two sides of the first semiconductor device 300.

In an example embodiment of the present inventive concept, the first and second semiconductor devices 300 and 400 may be mounted on the wiring layer 220 by a flip chip bonding method. Chip pads 310 of the first semiconductor device 300 may be electrically connected to the first bonding pads 230 of the wiring layer 220 by second conductive bumps 330. Chip pads 410 of the second semiconductor device 400 may be electrically connected to the first bonding pads 230 of the wiring layer 220 by second conductive bumps 430. For example, the second conductive bumps 330 and 430 may include micro bumps (uBumps).

For example, the first semiconductor device 300 may include a logic semiconductor device, and the second semiconductor device 400 may include a memory device. The logic semiconductor device may be an ASIC as a host such as a CPU, GPU, or SOC. The memory device may include a high bandwidth memory (HBM) device. In this case, the second semiconductor device may include a buffer die and a plurality of memory dies (chips) sequentially stacked on the buffer die. The buffer die and the memory dies may be electrically connected to each other by through silicon vias.

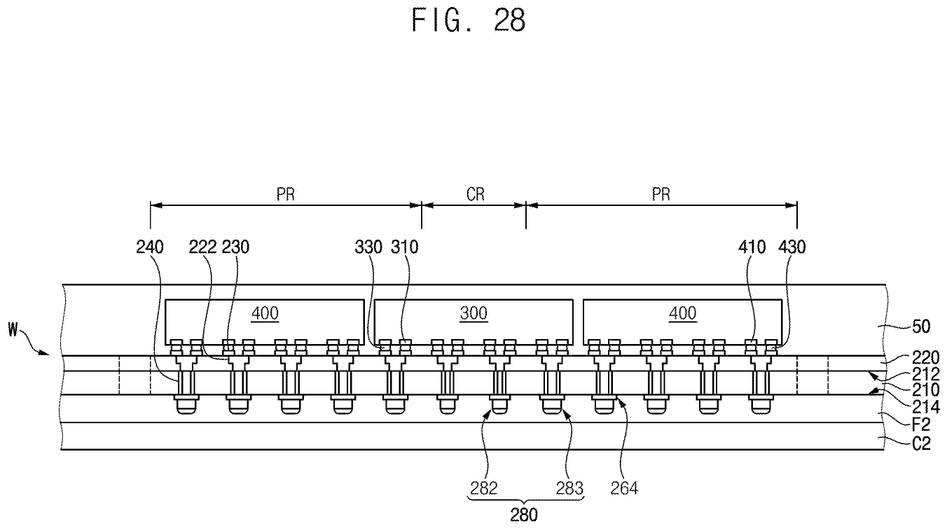

Referring to FIG. 28, a sealing material 50 may be formed on the wiring layer 220 and may cover the first semiconductor device 300 and the second semiconductor devices 400.

In an example embodiment of the present inventive concept, after forming the sealing material 50 that covers the first and second semiconductor devices 300 and 400 on the wiring layer 200, the sealing material 50 may be partially removed to expose upper surfaces of the first and second semiconductor devices 300 and 400.

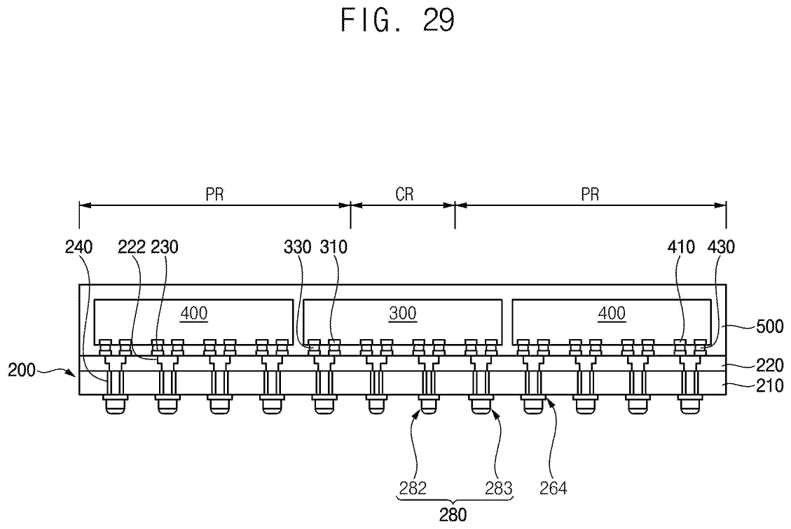

Referring to FIG. 29, the wafer W may be cut along the cutting region SR to form the individual interposer 200.

In an example embodiment of the present inventive concept, when the wafer W is sawed by a sawing process, a portion of the sealing material 50 on the cutting region SR may also be sawed to form a sealing member 500.

The interposer 200 may include a central region CR and a peripheral region PR at least partially surrounding the central region CR. The first conductive bumps 280 may include the first bump structures 282, which are disposed on the second bonding pads 264 in the central region CR and have a circular shape when viewed in plan view, and the second bump structures 283, which are disposed on the second bonding pads 264 in the peripheral region PR and have an elliptical shape when viewed in plan view.

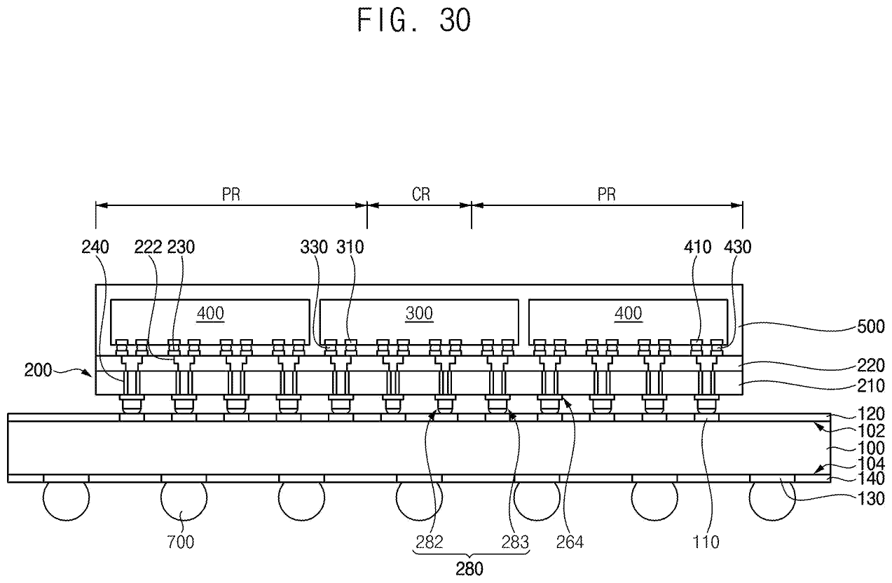

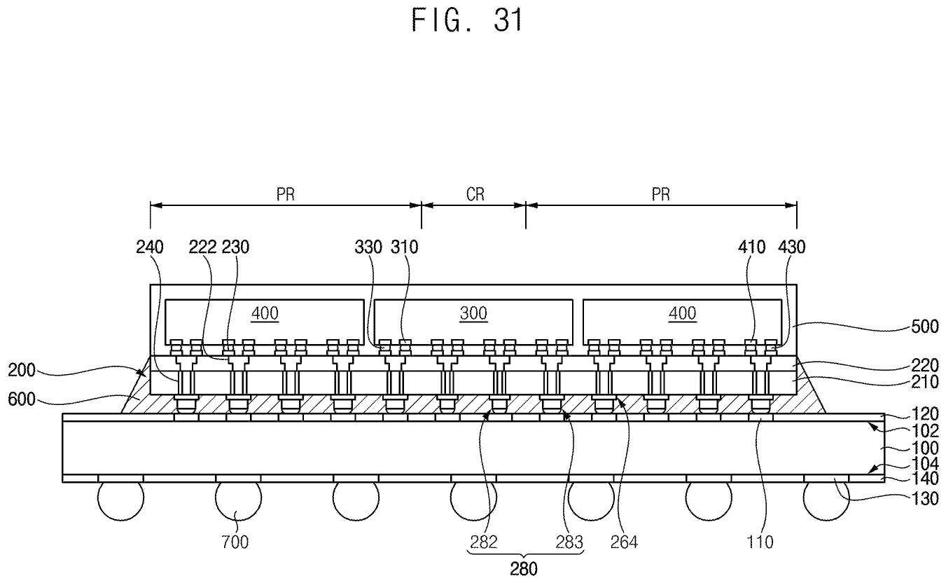

Referring to FIGS. 30 and 31, the interposer 200, on which the first and second semiconductor devices 300 and 400 are mounted, may be disposed on a package substrate 100, and an underfill member 600 may be formed between the interposer 200 and the package substrate 100.

In an example embodiment of the present inventive concept, the interposer 200 may be mounted on the package substrate 100 via the first conductive bumps 280. The interposer 200 may be adhered to the package substrate 100 by a thermal compression process.

An underfill solution may be dispensed between the interposer 200 and the package substrate 100 while positioning a dispenser nozzle at a corner of the interposer 200 or moving along edges of the interposer 200, and the underfill solution may be cured to form the underfill member 600.

The underfill member 600 may reinforce a gap between the interposer 200 and the package substrate 100. In addition, the second bump structures 283 having the elliptical shape may be arranged in the peripheral region PR of the interposer 200 to prevent misalignment while flip chip bonding of the interposer 200 to the package substrate 100. The first bump structures 282 having the circular shape may be arranged in the central region CR of the interposer 200 to further align the interposer 200 on the package substrate 100 and increase flowability of the underfill material in the central region CR during the underfill process to thereby prevent void traps.

Then, external connection members 700 such as solder balls may be formed on external connection pads 130 on a lower surface 104 of the package substrate 100 to complete a semiconductor package 10 of FIG. 1.

The semiconductor package 10 may include semiconductor devices such as logic devices or memory devices. The semiconductor package 10 may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package, comprising:
a package substrate;
an interposer including a substrate, a wiring layer, first bonding pads, second bonding pads, and first conductive bumps, wherein the substrate has a plurality of through electrodes formed to penetrate therethrough, wherein the wiring layer is provided on an upper surface of the substrate and has a plurality of wirings electrically connected to the plurality of through electrodes, wherein the first bonding pads are provided on the wiring layer and are electrically connected to the plurality of wirings, wherein the second bonding pads are provided on a lower surface of the substrate and are electrically connected to the plurality of through electrodes, wherein the first conductive bumps are disposed on the second bonding pads, respectively, wherein the interposer is mounted on the package substrate via the first conductive bumps;
first and second semiconductor devices provided on the interposer and spaced apart from each other, wherein front surfaces of each of the first and second semiconductor devices, on which chip pads are disposed, face the interposer, and wherein the first and second semiconductor devices are mounted on the interposer via second conductive bumps that are disposed on the chip pads, respectively;
a sealing member disposed on the interposer and covering the first and second semiconductor devices; and
an underfill member filling a space between the first conductive bumps that are between the package substrate and the interposer,
wherein the interposer includes a central region and a peripheral region adjacent to the central region, and
wherein the first conductive bumps include:
first bump structures disposed in the central region and having a circular shape; and
second bump structures disposed in the peripheral region and having an elliptical shape.

2. The semiconductor package of claim 1, wherein the second bump structures are arranged such that long axes of the second bump structures extend toward a center of the interposer.

3. The semiconductor package of claim 1, wherein each of the first bump structures includes a first pillar bump and a first solder bump, wherein the first pillar bump is disposed on a corresponding second bonding pad of the second bonding pads and has a circular shape, wherein the first solder bump is formed on the first pillar bump, and
each of the second bump structures includes a second pillar bump and a second solder bump, wherein the second pillar bump is disposed on a corresponding second bonding pad of the second bonding pads and has an elliptical shape, wherein second solder bump is formed on the second pillar bump.

4. The semiconductor package of claim 3, wherein each of the first and second pillar bumps includes copper.

5. The semiconductor package of claim 1, wherein each of the first bump structures has a diameter within a range of about 20 μm to about 180 μm, and each of the second bump structures has a long axis length within a range of about 25 μm to about 200 μm and a short axis length within a range of about 20 μm to about 180 μm.

6. The semiconductor package of claim 1, wherein each of the first conductive bumps has a thickness within a range of about 10 μm to about 100 μm.

7. The semiconductor package of claim 1, wherein a length of one side of the central region is within a range of about 200 μm to about 7,000 μm.

8. The semiconductor package of claim 1, wherein the interposer further includes a protective layer pattern provided on the lower surface of the substrate and exposing at least portions of the second bonding pads.

9. The semiconductor package of claim 8, wherein the protective layer pattern includes photo imagable dielectrics (PID).

10. The semiconductor package of claim 1, wherein a diameter of each of the first bonding pads is within a range of about 5 μm to about 40 μm, and a length of one side of each of the second bonding pads is within a range of about 25 μm to about 200 μm.

11. A semiconductor package, comprising:
a package substrate;
an interposer mounted on the package substrate via first conductive bumps;
first and second semiconductor devices disposed spaced apart from each other on the interposer and mounted on the interposer via second conductive bumps; and
an underfill member filling a space between the first conductive bumps that are disposed between the package substrate and the interposer,
wherein the interposer includes a central region and a peripheral region at least partially surrounding the central region, and
wherein the first conductive bumps include:
first bump structures disposed on second bonding pads, which are in the central region and on a lower surface of the interposer, respectively, and having a circular shape; and
second bump structures disposed on second bonding pads, which are in the peripheral region and on the lower surface of the interposer, respectively, and having an elliptical shape.

12. The semiconductor package of claim 11, wherein the interposer includes:
a substrate having a plurality of through electrodes formed to penetrate therethrough;
a wiring layer disposed on an upper surface of the substrate and having a plurality of wirings electrically connected to the plurality of through electrodes;
first bonding pads provided on the wiring layer and electrically connected to the plurality of wirings;
the second bonding pads provided on a lower surface of the substrate and electrically connected to the plurality of through electrodes; and
the first conductive bumps respectively disposed on the second bonding pads.

13. The semiconductor package of claim 12, wherein the interposer further includes a protective layer pattern provided on the lower surface of the substrate and exposing at least portions of the second bonding pads.

14. The semiconductor package of claim 13, wherein the protective layer pattern includes a photosensitive insulating material.

15. The semiconductor package of claim 11, wherein the second bump structures are arranged such that long axes of the second bump structures extend toward a center of the interposer.

16. The semiconductor package of claim 11, wherein each of the first bump structures includes a first pillar bump and a first solder bump, wherein the first pillar is disposed on a corresponding second bonding pad of the second bonding pads and has a circular shape, wherein the first solder bump is formed on the first pillar bump, and
each of the second bump structures includes a second pillar bump and a second solder bump, wherein the second pillar bump is disposed on a corresponding second bonding pad of the second bonding pads and has an elliptical shape and a second solder bump formed on the second pillar bump.

17. The semiconductor package of claim 16, wherein each of the first and second pillar bumps includes copper.

18. The semiconductor package of claim 11, wherein each of the first bump structures has a diameter within a range of about 20 μm to about 180 μm, and each of the second bump structures has a long axis length within a range of about 25 μm to about 200 μm and a short axis length within a range of about 20 μm to about 180 μm.

19. The semiconductor package of claim 11, wherein each of the first conductive bumps has a thickness within a range of about 10 μm to about 100 μm.

20. A semiconductor package, comprising:
a package substrate;
an interposer disposed on the package substrate, wherein the interposer includes a substrate, a wiring layer, first bonding pads, and second bonding pads, wherein the wiring layer is disposed on a first surface of the substrate and has a plurality of wirings, wherein the first bonding pads are disposed on the wiring layer and are electrically connected to the plurality of wirings, and wherein second bonding pads provided on a lower surface of the substrate;
first and second semiconductor devices arranged on the interposer and spaced apart from each other;
a plurality of first conductive bumps interposed between substrate pads of the package substrate and the second bonding pads of the interposer; and
a plurality of second conductive bumps interposed between the first bonding pads of the interposer and chip pads of the first and second semiconductor devices,
wherein the interposer includes a central region and a peripheral region at least partially surrounding the central region, and
wherein the plurality of first conductive bumps include:
first bump structures respectively disposed on the second bonding pads in the central region of the interposer and having a circular shape; and
second bump structures respectively disposed on the second bonding pads in the peripheral region of the interposer and having an elliptical shape.
